(19) United States
(12) Patent Application Publication
(10) Pub. No.: US 2019/0286765 A1
(43) Pub. Date: Sep. 19, 2019

(54) ANTENNA DESIGN APPARATUS AND COMPUTER READABLE RECORDING MEDIUM STORING ANTENNA DESIGN PROGRAM

(71) Applicant: FUJITSU LIMITED, Kawasaki-shi (JP)

(72) Inventors: Takashi YAMAGAJO, Yokosuka (JP); Sotaro KURIBAYASHI, Fukuoka (JP); Manabu KAI, Yokohama (JP)

(73) Assignee: FUJITSU LIMITED, Kawasaki-shi (JP)

(21) Appl. No.: 16/248,364

(22) Filed: Jan. 15, 2019

(30) Foreign Application Priority Data
Mar. 15, 2018 (JP) 2018-04 7735

(51) Int. Cl. G06F 17/50; H03H 7/38

(52) U.S. Cl. CPC G06F 17/5009; G06F 2217/16; H03H 7/38

(57) ABSTRACT

An antenna design apparatus includes a memory; and a processor coupled to the memory, wherein the processor calculates at least one circuit element value of a matching circuit for an antenna including loss resistance using S parameter data stored in the memory, obtains combined S parameter data in which a portion of the loss resistance of the matching circuit is incorporated in characteristics of the antenna by calculating the S parameter data while loss resistance of one of the calculated at least one circuit element value of the matching circuit which is disposed on a port side is incorporated in the characteristics of the antenna, and recalculates the at least one circuit element value of the matching circuit when the matching circuit is coupled to the antenna such that the at least one circuit element value matches the combined S parameter.

### CROSS-REFERENCE TO RELATED APPLICATION

This application is based upon and claims the benefit of priority of the prior Japanese Patent Application No. 2018-47735, filed on Mar. 15, 2018, the entire contents of which are incorporated herein by reference.

### FIELD

The embodiment discussed herein is related to an antenna design apparatus, an antenna design method, and a non-transitory computer-readable recording medium which stores an antenna design program.

### BACKGROUND

In recent years, miniaturized antennas have been widely used in various environments with miniaturization of antennas. Furthermore, matching circuits suitable for miniaturized antennas have been developed.

A technique of accommodating, in a thin electronic apparatus, a pair of a first variable capacity element and a first inductor which are connected to an antenna element in series and a pair of second variable capacity element and a second inductor which are connected to the antenna element in parallel in a matching circuit connected to an antenna has been used as an example.

Furthermore, a technique of generating an antenna model including an antenna and a matching circuit constituted by a matching element including a parasitic reactance and a loss resistance and determining whether a second antenna characteristic calculated using an input first antenna characteristic satisfies a desired standard value has been used.

Examples include Japanese Laid-open Patent Publication No. 2007-159083 and No. 2013-141081.

### SUMMARY

According to an aspect of the embodiments, an antenna design apparatus includes a memory; and a processor coupled to the memory, wherein the processor calculates at least one circuit element value of a matching circuit for an antenna including loss resistance using S parameter data stored in the memory, obtains combined S parameter data in which a portion of the loss resistance of the matching circuit is incorporated in characteristics of the antenna by calculating the S parameter data while loss resistance of one of the calculated at least one circuit element value of the matching circuit which is disposed on a port side is incorporated in the characteristics of the antenna, and recalculates the at least one circuit element value of the matching circuit when the matching circuit is coupled to the antenna such that the at least one circuit element value matches the combined S parameter.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a configuration in a case where matching circuits do not have a loss;

FIG. 2 is a diagram illustrating a configuration in a case where the matching circuits have a loss;

FIGS. 3A to 3C are diagrams illustrating a result of simulation in the case where the matching circuits do not have a loss;

FIGS. 4A to 4C are diagrams illustrating a result of simulation in the case where the matching circuits have a loss;

FIGS. 5A and 5B are diagrams illustrating a calculation method according to an embodiment;

FIG. 6 is a diagram illustrating a hardware configuration of an antenna design apparatus;

FIG. 7 is a diagram illustrating an example of a functional configuration of the antenna design apparatus;

FIG. 8 is a flowchart of an antenna design process performed by the antenna design apparatus;

FIG. 9 is a flowchart of a matching circuit calculation process;

FIG. 10 is a diagram illustrating an example of all connection patterns (first part);

FIG. 11 is a diagram illustrating the example of all the connection patterns (second part);

FIG. 12 is a diagram illustrating an example of a process in a case of a connection pattern No. 1;

FIG. 13 is a diagram illustrating an example of a process in a case of a connection pattern No. 22;

FIG. 14 is a diagram illustrating an example of a process in a case of a connection pattern No. 49;

FIG. 15 is a diagram illustrating an example of S parameter data;

FIGS. 16A and 16B are diagrams illustrating an example of a result of simulation according to a general technique; and

FIGS. 17A and 17B are diagrams illustrating an example of a result of simulation according to this embodiment.

### DESCRIPTION OF EMBODIMENTS

In recent years, a demand for antennas is increased in various environments with increase in an application range of Internet of Things (IoT). Antenna characteristics vary depending on a target to which an antenna is attached, a surrounding environment, or the like, and therefore, a large number of types of antenna have been designed.

Furthermore, a designed antenna is required to be suitable for an environment for performing verification of feasibility (Proof of Concept (PoC)) and verification of a value as business (Proof of Business (PoB)) or efficiently performing commercialization of product. Although characteristics of a matching circuit connected to an antenna is obtained by simulation in antenna design, a long period of time is required to obtain the characteristics since the matching circuit has a loss.

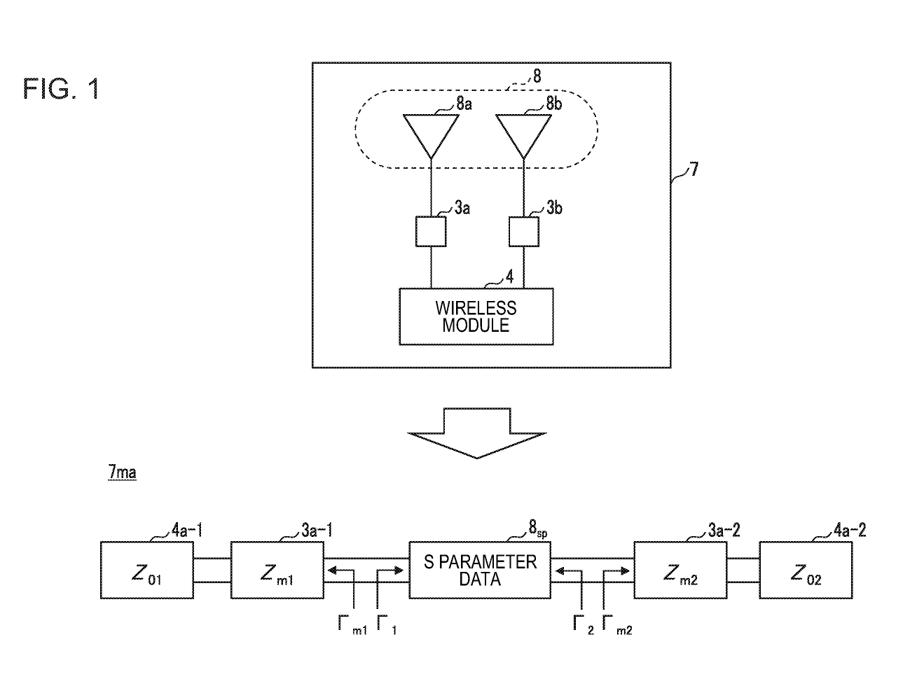

Hereinafter, an embodiment of the present disclosure will be described with reference to the accompanying drawings. First, a calculation method for determining matching circuits in a case where the matching circuits of two antennas do not have a loss will be described. FIG. 1 is a diagram illustrating a configuration in a case where matching circuits do not have a loss. In FIG. 1, an antenna apparatus 7 includes two antennas 8a and 8b, a matching circuit 3a connected to the antenna 8a, a matching circuit 3b connected to the antenna 8b, and a wireless module 4. The antennas 8a and 8b are collectively referred to as an antenna 8 where appropriate.

A model 7ma in which matching circuits do not have a loss includes S parameter data 8ₛₚ, matching circuits 3a-1 and 3a-2, and terminals 4a-1 and 4a-2. The S parameter data 8ₛₚ represents circuit characteristics of the two antennas 8a and 8b. The S parameter data 8ₛₚ indicates scattering parameters (S parameters) in step S11, step S22, step S21, and step S12.

The matching circuit 3a-1 indicates the matching circuit 3a and the matching circuit 3a-2 indicates the matching circuit 3b. Furthermore, the terminal 4a-1 indicates a power supply unit connected to the matching circuit 3a in the wireless module 4, and the terminal 4a-2 indicates a power supply unit connected to the matching circuit 3b in the wireless module 4. A resistance value Z₀ is assigned to the terminals 4a-1 and 4a-2 as a terminal condition.

In the model 7ma, a coefficient of reflection from a root of the antenna 8a toward the antenna 8a in the S parameter data 8ₛₚ is denoted by 1 and a coefficient of reflection from the root of the antenna 8a toward the matching circuit 3a and the wireless module 4 (the terminal 4a-1 (the power supply unit)) is denoted by ₘ₁. Similarly, a coefficient of reflection from a root of the antenna 8b toward the antenna 8b is denoted by ₂ and a coefficient of reflection from the root of the antenna 8b to the matching circuit 3b and the wireless module 4 (the terminal 4a-2 (the power supply unit)) is denoted by ₘ₂. The reflection coefficients ₘ₁ and ₘ₂ are represented as follows:

$${Γ}_{m 1} = \frac{{B}_{1} \pm \sqrt{{B}_{1}^{2} - 4 {\vert {C}_{1} \vert}^{2}}}{2 {C}_{1}} , \\ {Γ}_{m 2} = \frac{{B}_{2} \pm \sqrt{{B}_{2}^{2} - 4 {\vert {C}_{2} \vert}^{2}}}{2 {C}_{2}} \qquad [ Math . 1 ]$$

Impedances Zₘ₁ and Zₘ₂ of the matching circuits 3a-1 and 3a-2 which simultaneously satisfy the expressions above are determined.

Math. 1 is represented as follows:

$$\{ \begin{matrix}{Γ}_{m 1} = {Γ}_{1}^{*} , {Γ}_{m 2} = {Γ}_{2}^{*} , \\ {B}_{1} = 1 + {\vert {S}_{11} \vert}^{2} - {\vert {S}_{22} \vert}^{2} - {\vert Δ \vert}^{2} , \\ {B}_{2} = 1 + {\vert {S}_{22} \vert}^{2} - {\vert {S}_{11} \vert}^{2} - {\vert Δ \vert}^{2} , \\ {C}_{1} = {S}_{11} - Δ {S}_{22}^{*} , \\ {C}_{2} = {S}_{22} - Δ {S}_{11}^{*} , \\ Δ = {S}_{11} {S}_{22} - {S}_{12} {S}_{21}\end{matrix} \qquad [ Math . 2 ]$$

In the case where the matching circuits do not have a loss, the equations are solved such that the reflection coefficient ₘ₁ becomes a complex conjugate of the reflection coefficient ₁ and the reflection coefficient ₘ₂ becomes a complex conjugate of the reflection coefficient ₂. In this way, the impedance Zₘ₁ of the matching circuit 3a-1 and the impedance Zₘ₂ of the matching circuit 3a-2 may be obtained.

However, when the matching circuits 3a-1 and 3a-2 include a loss, the following condition is not satisfied.

Γₘ₁=Γ₁*,Γₘ₂=Γ₂*, [Math. 3]

When the calculation method described above is employed, characteristics of the matching circuits 3a-1 and 3a-2 may not be obtained, and a method for efficiently obtaining characteristics of the matching circuits has not been developed. Although numerical optimization approach may be employed, technical knowledge is required for setting of various parameters and the like associated with numerical analysis, and a long period of time is required for calculation since simulation is repeatedly performed.

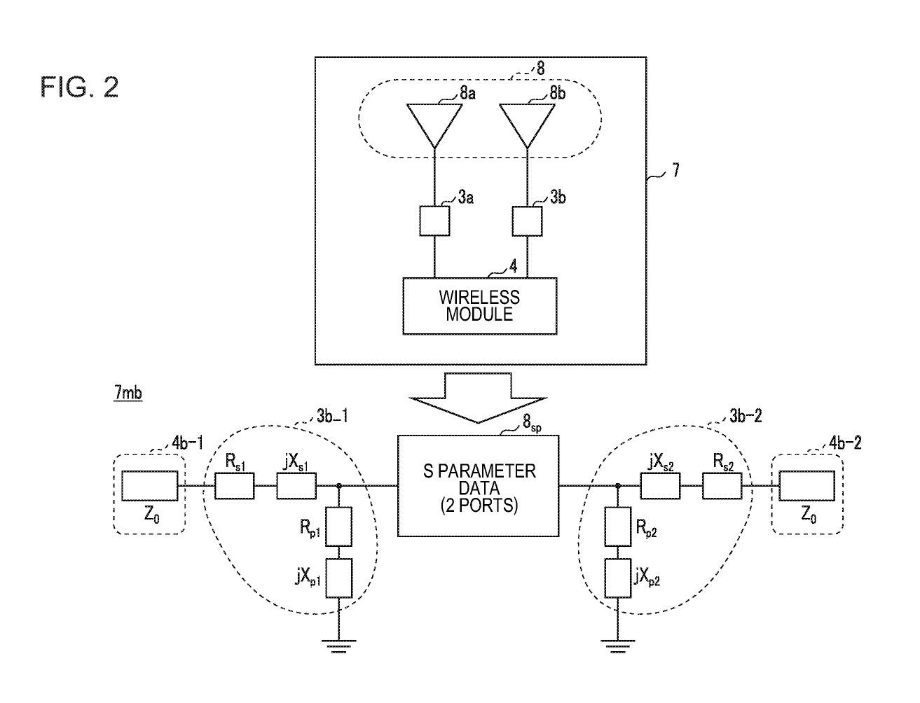

FIG. 2 is a diagram illustrating a configuration in the case where the matching circuits have a loss. A configuration of the antenna apparatus 7 of FIG. 2 is the same as that of FIG. 1.

A model 7mb in which matching circuits have a loss includes S parameter data 8ₛₚ, matching circuits 3b-1 and 3b-2, and terminals 4b-1 and 4b-2. The S parameter data 8ₛₚ is the same as that illustrated in FIG. 1.

The matching circuit 3b-1 indicates the matching circuit 3a and the matching circuit 3b-2 indicates the matching circuit 3b. The matching circuit 3b-1 includes circuits Rₛ₁ and jXₛ₁ which are connected in series to the antenna 8a of the antenna 8 indicated by the S parameter data 8ₛₚ and circuits Rₚ₁ and jXₚ₁ connected in parallel. Furthermore, the matching circuit 3b-2 includes circuits Rₛ₂ and jXₛ₂ which are connected in series to the antenna 8b of the antenna 8 indicated by the S parameter data 8ₛₚ and circuits Rₚ₂ and jXₚ₂ connected in parallel. Hereinafter, the antenna 8 indicated by the S parameter data 8ₛₚ is simply referred to as the S parameter data 8ₛₚ where appropriate.

Furthermore, the terminal 4b-1 indicates a power supply unit connected to the matching circuit 3a in the wireless module 4, and the terminal 4b-2 indicates a power supply unit connected to the matching circuit 3b in the wireless module 4. For example, a resistance value Z₀ of 50 Ohm is assigned to the terminals 4b-1 and 4b-2 as a terminal condition.

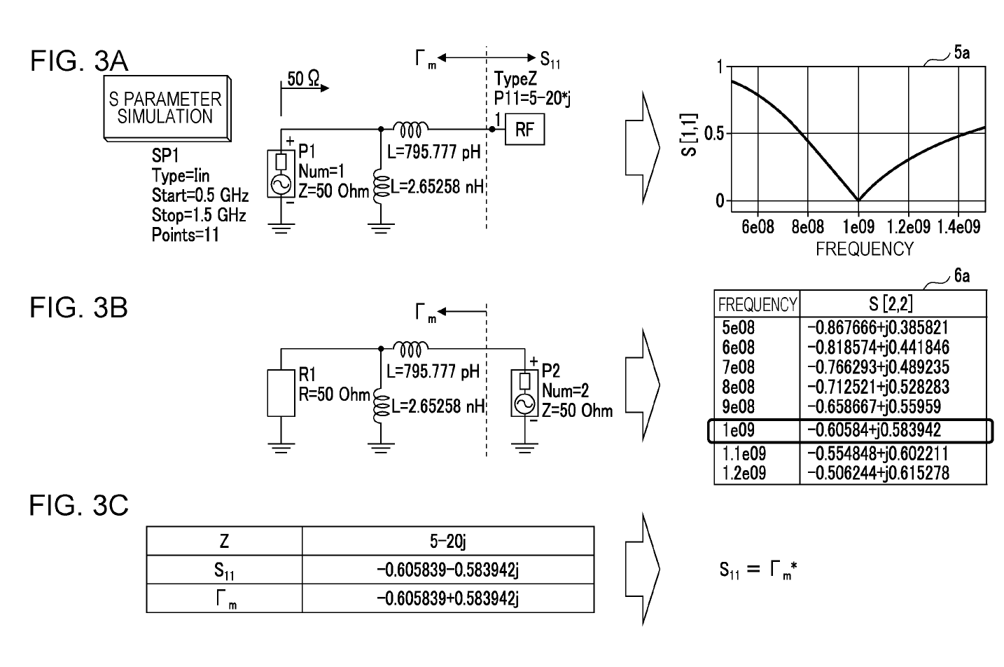

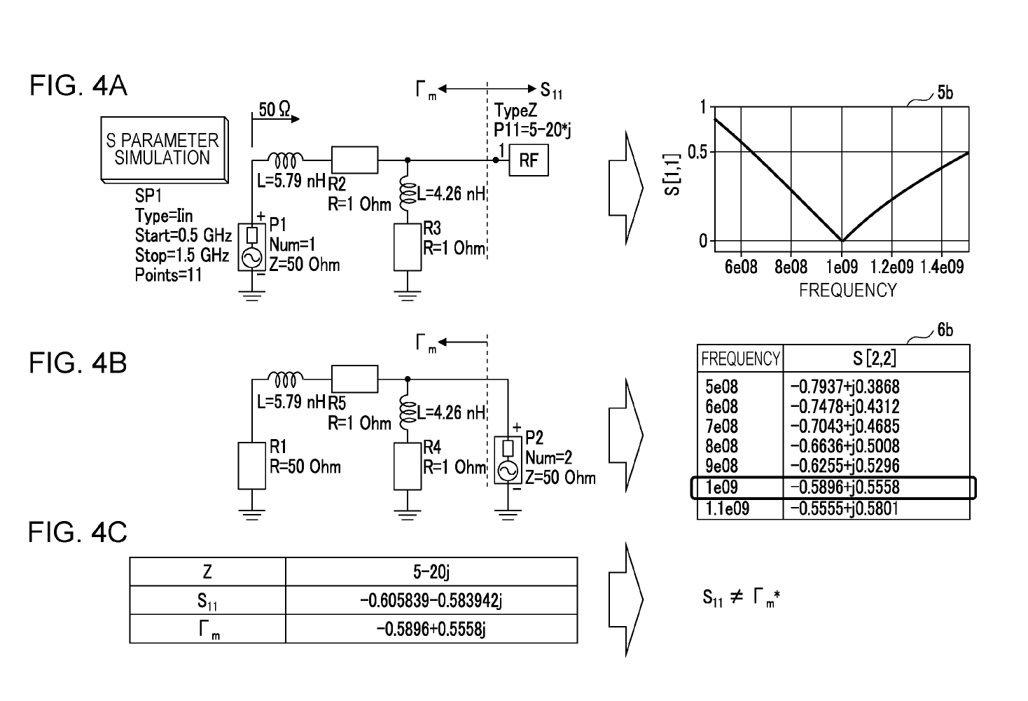

As described above, the model 7ma of FIG. 1 and the model 7mb of FIG. 2 have different circuit configurations. A difference of results obtained by the numerical analysis performed in the case where the matching circuits have a loss in the model 7ma and in the case where the matching circuits do not have a loss in the model 7mb will be described with reference to FIGS. 3A to 3C and FIGS. 4A to 4C. Although the case of a 1-port antenna is illustrated in FIGS. 3A to 3C and FIGS. 4A to 4C, the same is true of a 2-port antenna.

FIG. 3 is a diagram illustrating a simulation result in the case where the matching circuits do not have a loss. In FIG. 3, 1 GHz is set as a target frequency, Z=5-20*j is assigned to a radio frequency (RF) representing the antenna unit, and Z=50 Ohm is set to the terminals. S11 of the S parameter data 8ₛₚ is “−0.605839-0.583942j”.

In FIG. 3A, a result of an obtainment of a coefficient of reflection from a root of the antenna 8 toward the antenna 8 is illustrated. According to a graph 5a in which an axis of ordinates indicates the reflection coefficient and an axis of abscissae indicates a frequency, a reflection coefficient is zero at a target frequency of 1 GHz.

Furthermore, in FIG. 3B, a result of an obtainment of a coefficient ₘ of reflection from the root of the antenna 8 toward the power supply unit is illustrated. The reflection coefficient ₘ in the case of the target frequency of 1 GHz is “−0.605839-0.583942j” according to a table 6a indicating reflection coefficients for individual frequencies.

According to FIG. 3C, in the case where S11 is “−0.605839-0.583942j”, a reflection coefficient ₘ of “−0.605839+0.583942j” is obtained at the target frequency of 1 GHz by simulation of the S parameter data 8ₛₚ. Accordingly, “S11=ₘ*” is satisfied at the target frequency of 1 GHz, and therefore, matching is totally attained.

FIGS. 4A to 4C are diagrams illustrating a result of simulation in the case where the matching circuits have a loss. As with FIGS. 3A to 3C, a target frequency of 1 GHz is set, Z=5-20*j is assigned to a radio frequency (RF) representing the antenna unit, and Z=50 Ohm is set to the terminals in FIGS. 4A to 4C. Furthermore, a loss of 10 Ohm is assigned to the series connection side and a loss of 10 Ohm is assigned to the parallel connection side. S₁₁ of the S parameter data 8ₛₚ is “−0.605839-0.583942j” similarly to the case where the matching circuits do not have a loss.

In FIG. 4A, a result of an obtainment of a coefficient of reflection from the root of the antenna 8 toward the antenna 8 is illustrated. Referring to a graph 5b in which an axis of ordinates indicates the reflection coefficient and an axis of abscissae indicates a frequency, the reflection coefficient is zero at the target frequency of 1 GHz.

Furthermore, in FIG. 4B, a result of an obtainment of a coefficient ₘ of reflection from the root of the antenna 8 toward the power supply unit is illustrated. When referring to a table 6b indicating reflection coefficients for individual frequencies, a reflection coefficient ₘ at the target frequency of 1 GHz is “−0.5896+0.5558j”.

According to FIG. 4C, in the case where S₁₁ is “−0.605839-0.583942j”, a reflection coefficient ₘ of “−0.5896+0.5558j” is obtained at the target frequency of 1 GHz by simulation of the S parameter data 8ₛₚ. Accordingly, “S₁₁=ₘ*” is not satisfied at the target frequency of 1 GHz, and therefore, matching is not attained. In the case where the matching circuits have a loss as described above, impedances of the matching circuits may not be solved in an analysis manner.

In this embodiment, an antenna design apparatus and an antenna design program which address the foregoing problem are provided. The inventor found a technique of performing a calculation associated with a matching circuit at high speed by determining a matching element value in a state in which the matching circuit has a loss, combining a loss included in a circuit element with the S parameter data 8ₛₚ of the antenna 8, and thereafter, calculating the at least one circuit element value of the matching circuit again.

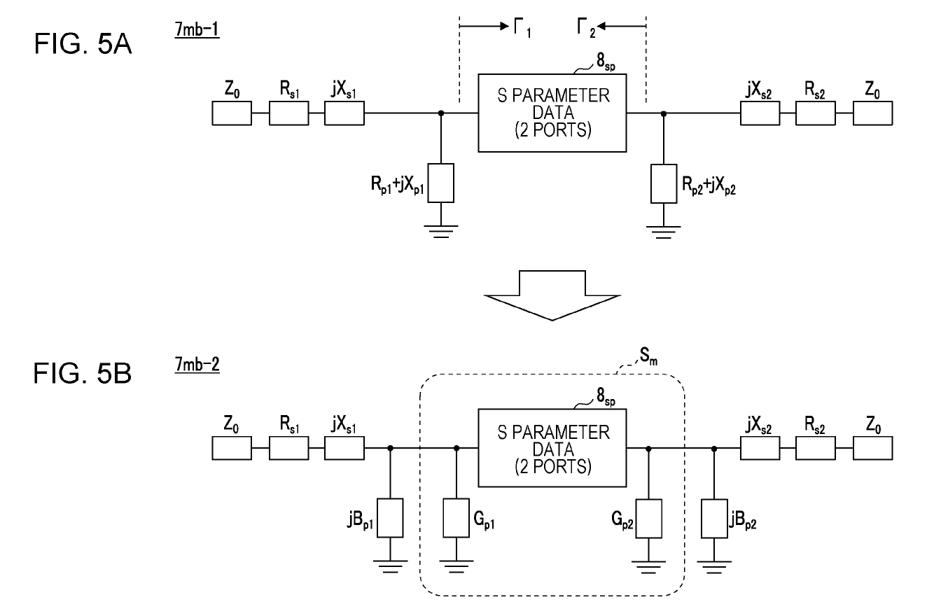

FIGS. 5A and 5B are diagrams illustrating a calculation method according to this embodiment. FIG. 5A is a diagram illustrating a step I. In FIG. 5A, a model 7mb-1 in which the circuit Rₛ₁ and the circuit jXₛ₁ in the matching circuit 3b-1 in the model 7mb of FIG. 2 are represented by a single circuit and the circuit Rₚ₁ and the circuit jXₚ₁ in the matching circuit 3b-2 in the model 7mb of FIG. 2 are represented by a single circuit is illustrated.

50 Ohm is assigned to Z₀, the S parameter data 8ₛₚ is given, and Rₛ₁, Rₚ₁, Rₛ₂, and Rₚ₂ which indicate losses are given. Although the losses Rₛ₁, Rₚ₁, Rₛ₂, and Rₚ₂ are given in the step I, a circuit element value is calculated by performing a calculation for equalizing an impedance to Z₀ when matching circuits which do not have a loss is connected. Reflection coefficients ₁ and ₂ are obtained by a general calculation method.

As illustrated in FIGS. 4A to 4C, the reflection coefficient ₁ does not match S₁₁ of the S parameter data 8ₛₚ in the step I. The reflection coefficient ₂ does not match S₂₂ of the S parameter data 8sp. The step II is performed in the mismatching state.

In the step II of FIG. 5B, reciprocals of the circuit Rₚ₁+jXₚ₁ and the circuit Rₚ₂+jXₚ₂ which are connected to each other in parallel in the model 7mb-1 of FIG. 5A are individually obtained and a real number is set to a denominator. As a general expression, a calculation is performed in accordance with Math. 4 so that an impedance (R+jX) is subjected to circuit conversion to obtain an admittance (G+jB).

$$G + jB = \frac{1}{R + jX} = \frac{R - jX}{{R}^{2} + {X}^{2}} \\ G = \frac{R}{{R}^{2} + {X}^{2}} , B = \frac{- X}{{R}^{2} + {X}^{2}} \qquad [ Math . 4 ]$$

According to Math 4, values of Gₚ₁ and Bₚ₁ may be obtained by converting Rₚ₁+jXₚ₁ into Gₚ₁+jBₚ₁. By this conversion, the circuit configuration in which the circuit element Rₚ₁ and the circuit element jXₚ₁ are connected to each other in the same parallel connection is converted into a circuit configuration in which the circuit element Gₚ₁ and the circuit element jBₚ₁ are individually connected in parallel.

Similarly, values of Gₚ₂ and Bₚ₂ may be obtained by converting Rₚ₂+jXₚ₂ into Gₚ₂+jBₚ₂. By this conversion, the circuit configuration in which the circuit element Rₚ₂ and the circuit element jXₚ₂ are connected to each other in the same parallel connection is converted into a circuit configuration in which the circuit element Gₚ₂ and the circuit element jBₚ₂ are individually connected in parallel.

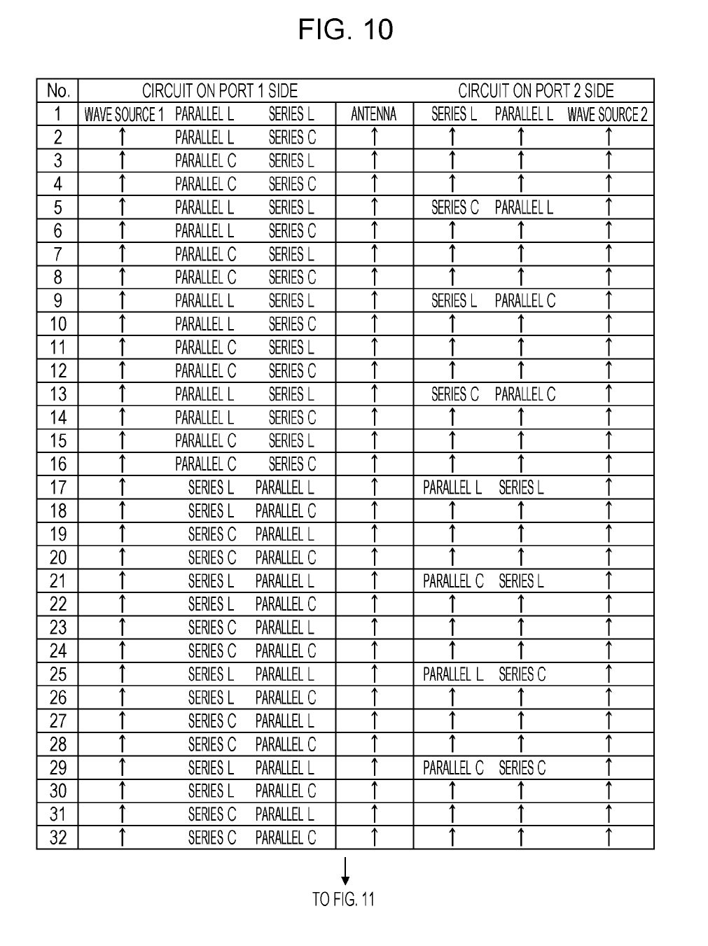

S parameter data Sₘ is obtained by combining the obtained circuit elements Gₚ₁ and Gₚ₂ with the S parameter data 8ₛₚ. Then values of circuit elements Xₛ₁, Xₛ₂, Bₚ₁, and Bₚ₂ are obtained by a calculation so that matching with the S parameter data Sₘ obtained after the combining (hereinafter referred to as “combined S parameter data Sₘ”) is attained. Accordingly, at least one circuit element value of the matching circuits may be obtained taking Gₚ₁ and Gₚ₂ corresponding to losses of the matching circuits into consideration. The example of the circuit configuration illustrated in FIGS. 5A and 5B corresponds to a connection pattern No. 17 in FIG. 10 described below.

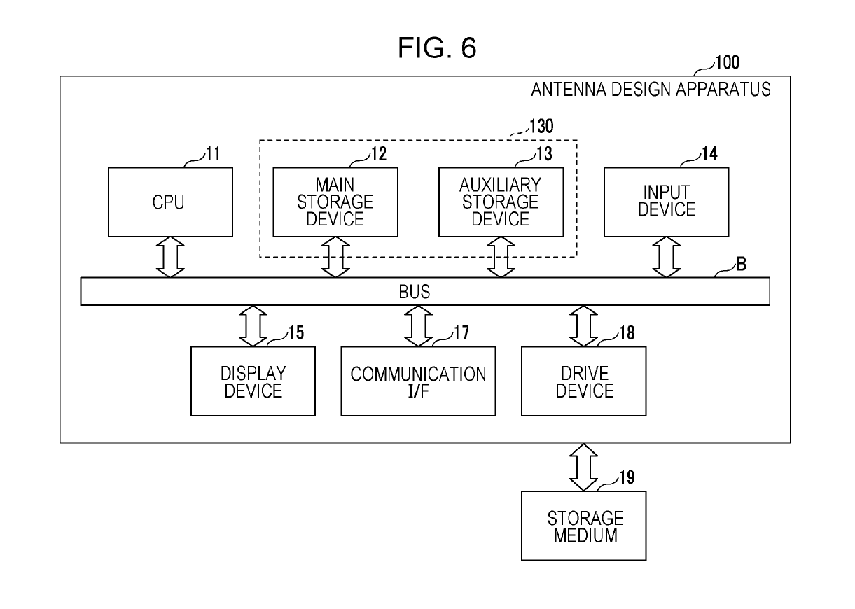

The antenna design apparatus which performs the foregoing steps I and II has a hardware configuration illustrated in FIG. 6. FIG. 6 is a diagram illustrating a hardware configuration of the antenna design apparatus. In FIG. 6, an antenna design apparatus 100 is an information processing apparatus controlled by a computer and includes a central processing unit (CPU) 11, a main storage device 12, an auxiliary storage device 13, an input device 14, a display device 15, a communication interface (I/F) 17, and a drive device 18 which are connected to a bus B.

The CPU 11 corresponds to a processor which controls the antenna design apparatus 100 in accordance with a program stored in the main storage device 12. The main storage device 12 which is a random access memory (RAM), a read only memory (ROM), or the like stores or temporarily saves programs to be executed by the CPU 11, data required for processes performed by the CPU 11, data obtained by the processes performed by the CPU 11, and the like.

The auxiliary storage device 13 which is a hard disk drive (HDD) or the like stores data including programs for performing various processes. A number of the programs stored in the auxiliary storage device 13 are loaded in the main storage device 12 and executed by the CPU 11 so that various processes are realized. The main storage device 12 and the auxiliary storage device 13 are collectively referred to as a storage unit 130. The HDD, the main storage device, and the like are individually referred to as a memory where appropriate.

The input device 14 includes a mouse and a keyboard and is used by a user, such as a designer, to input various information required for processes to be performed by the antenna design apparatus 100. The display device 15 displays the required various information under control of the CPU 11. The input device 14 and the display device 15 may be integrated as a user interface, such as a touch panel. The communication I/F 17 performs communication through a wired network or a wireless network. The communication performed by the communication I/F 17 is not limited to the wireless communication or the wired communication.

The drive device 18 serves as an interface between a storage medium 19 (such as a compact disc read-only memory (CD-ROM)) set in the drive device 18 and the antenna design apparatus 100.

The programs which realize the processes to be performed by the antenna design apparatus 100 are supplied to the antenna design apparatus 100 by the storage medium 19, such as a CD-ROM, for example. The programs which realize various processes according to this embodiment described below are stored in the storage medium 19, and the programs stored in the storage medium 19 are installed in the antenna design apparatus 100 through the drive device 18. The installed programs are executable by the antenna design apparatus 100.

The storage medium 19 which stores the programs is not limited to the CD-ROM as long as the storage medium 19 is at least one non-transitory tangible medium having a computer readable structure. Examples of the computer readable storage medium include, in addition to the CD-ROM, a portable storage medium, such as a digital versatile disk (DVD) or a USB memory, and a semiconductor memory, such as a flash memory.

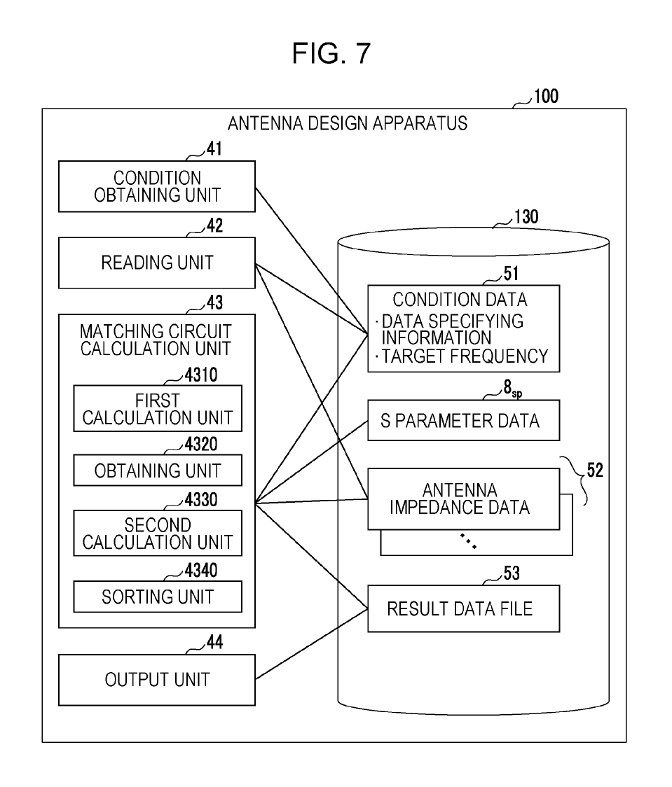

FIG. 7 is a diagram illustrating an example of a functional configuration of the antenna design apparatus 100. In FIG. 7, the antenna design apparatus 100 includes a condition obtaining unit 41, a reading unit 42, a matching circuit calculation unit 43, and an output unit 44. The storage unit 130 stores conditional data 51, the S parameter data 8ₛₚ, antenna impedance data 52, a result data file 53, and the like.

The condition obtaining unit 41 obtains the conditional data 51 from the user and stores the conditional data 51 in the storage unit 130. The conditional data 51 indicates data specifying information for specifying the antenna impedance data 52, a target frequency, and the like.

The reading unit 42 reads the antenna impedance data 52 from the storage unit 130 using the data specifying information. The antenna impedance data 52 is data files provided in advance, generated for individual antennas, and stored in the storage unit 130. Impedances of the antenna 8 are associated with frequencies and are recorded in the antenna impedance data 52.

The S parameter data 8ₛₚ described above is calculated using the antenna impedance data 52 specified by the conditional data 51 and a reference impedance of 50 Ohm or the like and represented by two or four reflection coefficients. In a case where two antennas 8 are used, S₁₁, S₁₂, S₂₁, and S₂₂ are obtained. The S parameter data 8ₛₚ may be calculated by the reading unit 42 in advance and assigned to the matching circuit calculation unit 43 or may be calculated by the matching circuit calculation unit 43. The two or four reflection coefficients obtained by the calculation are initial values of the S parameter data 8ₛₚ in the matching circuit calculation unit 43.

The matching circuit calculation unit 43 calculates impedances at a time of connection to the matching circuits using the conditional data 51 and the antenna impedance data 52 read by the reading unit 42, obtains at least one circuit element value, and thereafter, sorts the at least one circuit element value in descending order of a bandwidth. Different impedances are calculated for different matching circuit configurations. The matching circuit calculation unit 43 includes a first calculation unit 4310, an obtaining unit 4320, a second calculation unit 4330, and a sorting unit 4340.

The first calculation unit 4310 obtains, by calculation, impedances of the matching circuits 3b-1 and 3b-2 which equalize the impedance of the antenna 8 at the target frequency to the terminal Z₀ using the S parameter data 8ₛₚ without taking loss resistance of the matching circuits 3b-1 and 3b-2 into consideration. The impedances of the matching circuits 3b-1 and 3b-2 obtained by the calculation includes loss resistance.

For example, the first calculation unit 4310 obtains the impedances (Rₛ₁+jXₛ₁ and Rₚ₁+jXₚ₁) of the matching circuit 3b-1 by calculation. Similarly, the first calculation unit 4310 obtains the impedances (Rₛ₂+jXₛ₂ and Rₚ₂+jXₚ₂) of the matching circuit 3b-2 by calculation. The resistance R (Rₛ₁, Rₚ₁, Rₛ₂, and Rₚ₂) represented by real numbers are given in advance, and the first calculation unit 4310 obtains a reactance X (Xₛ₁, Xₚ₁, Xₛ₂, and Xₚ₂) without taking the loss resistance into consideration.

The obtaining unit 4320 calculates the S parameter data 8ₛₚ again while incorporating the resistance R caused by the series connection or the parallel connection on the port sides of the antenna 8 so as to obtain combined S parameter data Sₘ.

When the resistance R of the series connection is to be incorporated, the obtaining unit 4320 simply incorporates the resistance R in characteristics of a port to be connected, calculates the S parameter data 8ₛₚ again, and obtains the S parameter data Sₘ. When the resistance R of the parallel connection is to be incorporated, the obtaining unit 4320 converts impedance (R+jX) into admittance (G+jB), and thereafter, calculates the S parameter data 8ₛₚ again while incorporating the resistance R in the characteristics of a port to which conductance G is to be connected so as to obtain the S parameter data Sₘ (refer to FIG. 5B).

The second calculation unit 4330 calculates impedances when the matching circuits 3b-1 and 3b-2 are connected to the antenna 8 so that the impedances match the S parameter data Sₘ obtained by the obtaining unit 4320. The second calculation unit 4330 obtains values of the circuit elements Xₛ₁, Xₚ₁, Xₛ₂, and Xₚ₂ having improved accuracy. When conversion into admittance (G+jB) is performed, a susceptance B obtained by a calculation corresponds to a reactance X of the parallel connection.

The sorting unit 4340 sorts the matching circuit configurations in descending order of a bandwidth or in ascending order of a Q factor. The result data file 53 indicating a result of the sorting is stored in the storage unit 130.

The output unit 44 displays an optimum one of the matching circuit configurations in the display device 15 with reference to the result data file 53. A matching circuit configuration of a widest bandwidth or a matching circuit configuration of a smallest Q factor is displayed in the display device 15.

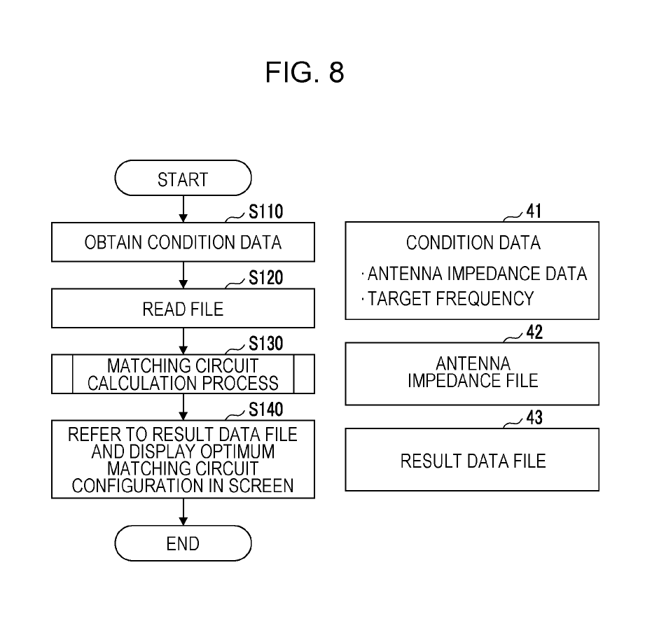

FIG. 8 is a flowchart of an antenna design process performed by the antenna design apparatus 100. In FIG. 8, the condition obtaining unit 41 obtains the conditional data 51 from the user and stores the conditional data 51 in the storage unit 130 (step S110). Next, the reading unit 42 reads the antenna impedance data 52 from the storage unit 130 (step S120), and the matching circuit calculation unit 43 performs a matching circuit calculation process (step S130).

When the matching circuit calculation process is terminated, the output unit 44 displays an optimum one of the matching circuit configurations in a screen of the display device 15 with reference to the result data file 53 including a result of the calculation obtained by the matching circuit calculation unit 43 (step S140). A matching circuit configuration of a largest band or a smallest Q factor is displayed in the display device 15. A number of the matching circuit configurations which are in predetermined upper order in the sorting may be displayed as candidates. Then the antenna design process is terminated.

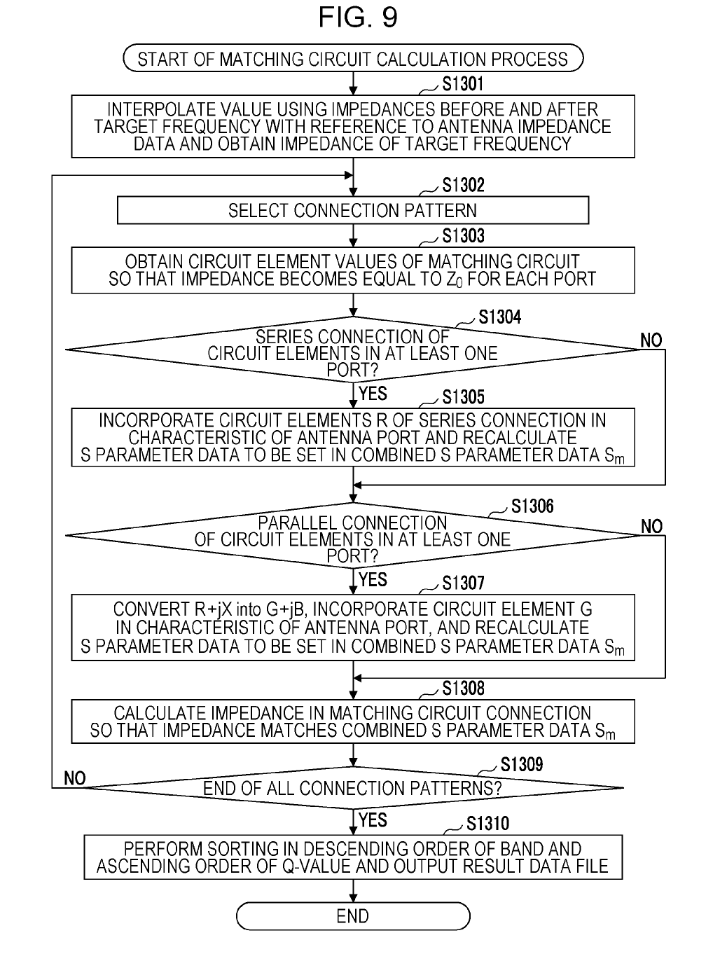

FIG. 9 is a flowchart of the matching circuit calculation process. In FIG. 9, the matching circuit calculation unit 43 obtains a target frequency from the conditional data 51 and interpolates a value using impedances before and after the target frequency with reference to the antenna impedance data 52 so as to obtain an impedance of the target frequency (step S1301).

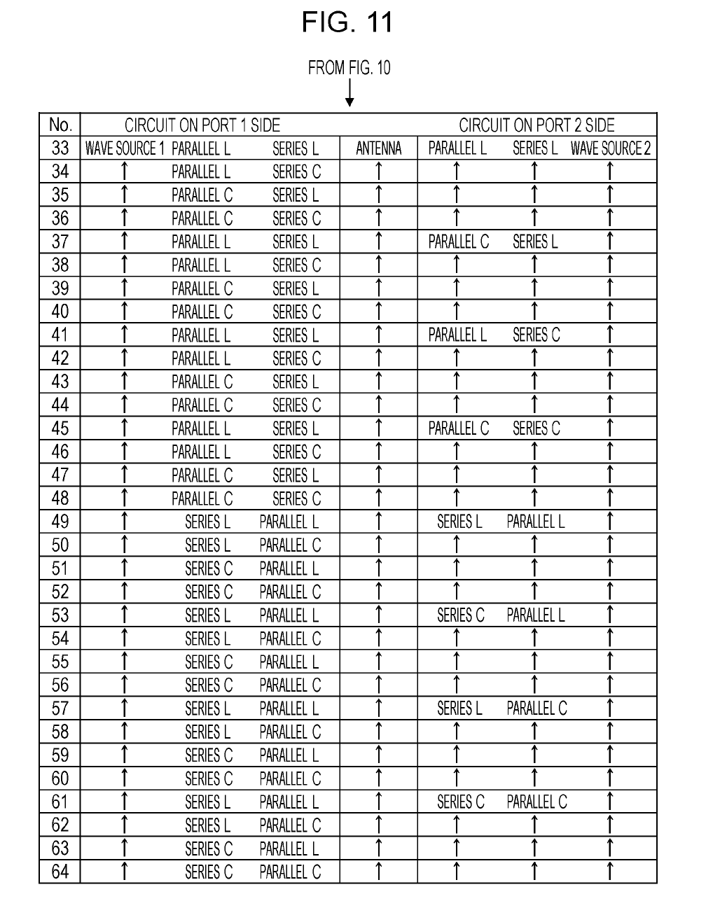

The matching circuit calculation unit 43 performs a process from step S1302 to step S1308 on all connection patterns of circuit elements included in the matching circuit. The connection patterns are illustrated in FIGS. 10 and 11. In the matching circuit calculation unit 43, the first calculation unit 4310 selects one of the connection patterns (step S1302).

The first calculation unit 4310 calculates a circuit element value of the matching circuit which equalizes an impedance of the antenna 8 obtained in step S1301 to the resistance value Z₀ of the terminal for each port using the circuit configuration corresponding to the selected connection pattern (step S1303). The first calculation unit 4310 obtains circuit element values Xₛ₁ and Xₚ₁ so that the impedance of the antenna 8 becomes equal to the resistance value Z₀ when the matching circuit near the port 1 is connected to the reflection coefficient ₁. Similarly, the first calculation unit 4310 obtains circuit element values Xₛ₂ and Xₚ₂ so that the impedance of the antenna 8 becomes equal to the resistance value Z₀ when the matching circuit near the port 2 is connected to the reflection coefficient ₂. Accordingly, the first calculation unit 4310 obtains four circuit element values Xₛ₁, Xₚ₁, Xₛ₂, and Xₚ₂.

In the matching circuit calculation unit 43, the obtaining unit 4320 determines whether the circuit elements are connected to at least one port in series in the circuit configuration (step S1304). When the determination is negative (NO in step S1304), the obtaining unit 4320 proceeds to step S1306. On the other hand, when the determination is affirmative (YES in step S1304), the obtaining unit 4320 calculates the S parameter data 8ₛₚ again while incorporating a circuit element R of the series connection in the characteristics of the port of the antenna 8 so as to set the S parameter data 8ₛₚ as combined S parameter data Sₘ (step S1305). Furthermore, the obtaining unit 4320 replaces the S parameter data 8ₛₚ with the combined S parameter data Sₘ.

The obtaining unit 4320 determines whether the circuit elements are connected to at least one port in parallel in the circuit configuration (step S1306). When the determination is negative (NO in step S1306), the obtaining unit 4320 proceeds to step S1308.

On the other hand, when the determination is affirmative (YES in step S1306), the obtaining unit 4320 converts R+jX into G+jB in accordance with Math 4 for each circuit element of the parallel connection and calculates the S parameter data 8ₛₚ again while incorporating the circuit element G in the characteristics of the port of the antenna 8 so as to set the S parameter data 8ₛₚ as the combined S parameter data Sₘ (step S1307).

In a case where only the circuit elements of the series connection are connected to one port (YES in step S1304) and the circuit elements of the parallel connection are connected to the other port (YES in step S1306), the combined S parameter data Sₘ set in step S1305 is updated in step S1307.

When obtaining the combined S parameter data Sₘ including the loss of the matching circuit, the second calculation unit 4330 calculates an impedance obtained when the matching circuit is connected to the antenna 8 such that matching with the combined S parameter data Sₘ is attained (step S1308). The second calculation unit 4330 updates the reflection coefficient ₁ and ₂ using the combined S parameter data Sₘ.

The second calculation unit 4330 obtains circuit element values Xₛ₁ and Xₚ₁ (or Bₚ₁) such that the impedance obtained when the matching circuit near the port 1 is connected to the updated reflection coefficient ₁ becomes equal to the resistance value Z₀. Similarly, the second calculation unit 4330 obtains circuit element values Xₛ₂ and Xₚ₂ (or Bₚ₂) such that the impedance obtained when the matching circuit near the port 2 is connected to the updated reflection coefficient ₂ becomes equal to the resistance value Z₀. Accordingly, four circuit element values Xₛ₁, Xₚ₁ (or Bₚ₁), Xₛ₂, and Xₚ₂ (or Bₚ₂) are obtained taking the loss into consideration.

The matching circuit calculation unit 43 determines whether all the connection patterns have been selected (step S1309). When the determination is negative (NO in step S1309), the matching circuit calculation unit 43 updates the S parameter data 8ₛₚ to an initial value and returns to step S1302 where the process described above is performed again. When the determination is affirmative (YES in step S1309), the sorting unit 4340 of the matching circuit calculation unit 43 sorts all the connection patterns in descending order of bandwidth based on the calculated impedance and outputs the result data file 53 to the storage unit 130 (step S1310). Then the matching circuit calculation unit 43 terminates the matching circuit calculation process.

In step S1310, the sorting unit 4340 may obtain a Q factor using the combined S parameter data Sₘ and sort all the connection patterns in ascending order of the Q factor. In a case where the two antennas 8 are used, the sorting unit 4340 sorts all the connection patterns such that sums of a Q factor calculated based on S₁₁ at a time of matching and a Q factor calculated based on S₂₂ are sorted in ascending order.

According to the matching circuit calculation process, in the matching circuit including the circuit elements connected to the port of the antenna 8 in series and the circuit elements connected to the port of the antenna 8 in parallel, at least one circuit element value of the matching circuit corresponding to all 64 connection patterns may be obtained in accordance with order of connection to the port of the antenna 8 and types of the circuit elements. Furthermore, the matching circuit calculation process of this embodiment is applicable to a case of 1-port antenna and a case of 2-port antenna.

FIGS. 10 and 11 are diagrams illustrating an example of all the connection patterns. The connection patterns of the circuit elements in the 2-port antenna matching circuit schematically indicates a circuit configuration including circuits connected in series between the port 1 and the wave source 1 and between the port 2 and the wave source 2 and circuits which are connected in parallel near the port 1 and the port 2 and which are grounded, circuits which are connected in parallel near the port 1 and near the wave source 2 and which are grounded, or circuits which are connected in parallel near the port 2 and near the wave source 1.

As an example, in FIGS. 10 and 11, combinations of a type of connection and a type of circuit element are successively illustrated in a direction of connection to the wave source 1 and the wave source 2 using the antenna 8 at the center. For example, “parallel L” indicates parallel connection of inductors L, and “serial L” indicates series connection of inductors L. Furthermore, “parallel C” indicates parallel connection of capacitors C, and “serial C” indicates series connection of capacitors C. Furthermore, a sign “ ” indicates “same as above”. Hereinafter, the inductor L is referred to as a circuit element L, and the capacitor C is referred to as a circuit element C.

Furthermore, the circuit elements L or the circuit elements C connected to the port 1 in series or in parallel are referred to as a first circuit and the circuit elements L or the circuit elements C connected to the wave source 1 (the power supply unit) in series or in parallel are referred to as a second circuit. Each of the first circuit and the second circuit includes a loss. A first circuit and a second circuit are similarly defined for the port 2, and each of the first circuit and the second circuit includes a loss.

As described above, the first circuit or the second circuit including the circuit elements L is denoted by R+jX (impedance). Furthermore, the first circuit or the second circuit including the circuit elements C is denoted by R-jX (impedance). A resistance R indicates a loss.

In connections No. 1 to No. 16 of FIG. 10, a circuit configuration in which a first circuit is connected to the port 1 and the port 2 in series and a second circuit is connected in parallel on the wave source 1 side and the wave source 2 side (the power source side) is illustrated. In this circuit configuration, a value of the circuit element R in a loss portion among the circuit element R and a circuit element (+jX or −jX) indicating the first circuit connected to the port 1 and the port 2 in series is incorporated in the characteristics of the port 1 and the port 2 and regenerates the S parameter data 8ₛₚ.

The regeneration of the S parameter data 8ₛₚ while the value of the circuit element R in the loss portion is incorporated in the characteristics of the port 1 and/or the port 2 is simply referred to as “combining of the loss portion with the S parameter data 8ₛₚ” hereinafter.

Furthermore, in connection patterns No. 17 to No. 32, a circuit configuration in which a first circuit is connected to the port 1 and the port 2 in parallel and a second circuit is connected in series on the wave source 1 side and the wave source 2 side (the power source side) is illustrated. In this circuit configuration, the first circuit connected to the port 1 and the port 2 in parallel is divided into two circuit elements (G and jB) connected in parallel, and one of the divided two circuit elements which corresponds to a loss portion (G) is combined with the S parameter data 8ₛₚ.

In connection patterns No. 33 to No. 48 of FIG. 11, a connection configuration in which a first circuit is connected to the port 1 in series, a second circuit is connected in parallel on the wave source 1 side (the power source side), the first circuit is connected to the port 2 in parallel, and the second circuit is connected in series on the wave source 2 side (the power source side) is illustrated. In this circuit configuration, a loss portion (R) among the circuit element R and the circuit element (+jX or −jX) indicating the first circuit connected to the port 1 in series is combined with the S parameter data 8ₛₚ. On the other hand, on the port 2 side, the first circuit connected to the port 2 in parallel is divided into two circuit elements (G and jB) connected in parallel, and one of the divided two circuit elements which corresponds to a loss portion (G) is combined with the S parameter data 8ₛₚ.

In connection patterns No. 49 to No. 64, a connection configuration in which a first circuit is connected to the port 1 in parallel, a second circuit is connected in series on the wave source 1 side (the power source side), the first circuit is connected to the port 2 in series, and the second circuit is connected in parallel on the wave source 2 side (the power source side) is illustrated. In this circuit configuration, a loss portion (R) among the circuit element R and the circuit element (+jX or −jX) indicating the first circuit connected to the port 2 in series is combined with the S parameter data 8ₛₚ. Then, the first circuit connected to the port 2 in parallel is divided into two circuit elements (G and jB) connected in parallel, and one of the divided two circuit elements which corresponds to a loss portion (G) is combined with the S parameter data 8ₛₚ.

An example of a process from step S1304 to step S1308 of FIG. 9 for the connection patterns Nos. 1, 22, and 49 in all the connection patterns illustrated in FIGS. 10 and 11 will be described.

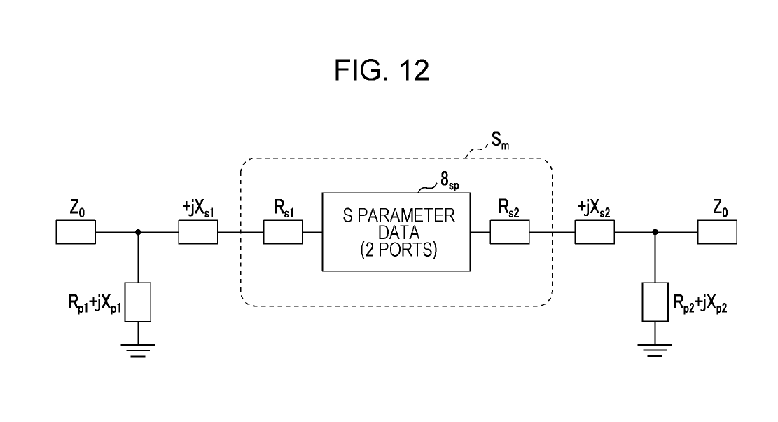

FIG. 12 is a diagram illustrating an example of a process in a case of the connection pattern No. 1. In FIG. 12, a model of an adjustment circuit in the connection pattern No. 1 is illustrated. In the connection pattern No. 1, the circuit element L is connected to the port 1 in series on the port 1 side and the circuit element L is connected in parallel and grounded on the wave source 1 side. The circuit element L connected to the port 1 in series is indicated by the circuit Rₛ₁ and the circuit jXₛ₁, and the circuit element L which is connected in parallel on the wave source 1 side and which is grounded is indicated by the circuit (Rₚ₁+jXₚ₁).

Furthermore, the circuit element L is connected to the port 2 in series on the port 2 side and the circuit element L is connected in parallel and grounded on the wave source 2 side. The circuit element L connected to the port 2 in series is indicated by the circuit Rₛ₂ and the circuit jXₛ₂, and the circuit element L which is connected in parallel and which is grounded is indicated by the circuit (Rₚ₂+jXₚ₂). Z₀(50) is given to the wave source 1 and the wave source 2.

Since the circuit element L is connected to the port 1 and the port 2 in series (YES in step S1304), loss portions (Rₛ₁, Rₛ₂) of the circuit elements L connected to the port 1 and the port 2 in series are combined with the S parameter data 8ₛₚ so that combined S parameter data Sm is obtained (step S1305).

In the connection pattern No. 1, a circuit element connected to the port 1 or the port 2 in parallel does not exist, and therefore, the process in step S1307 is not performed. Accordingly, impedance at a time of matching circuit connection is calculated such that the impedance matches the combined S parameter data Sₘ obtained in step S1305 (step S1308). As a result, values of Xₛ₁, Xₚ₁, Xₛ₂, and Xₚ₂ are obtained.

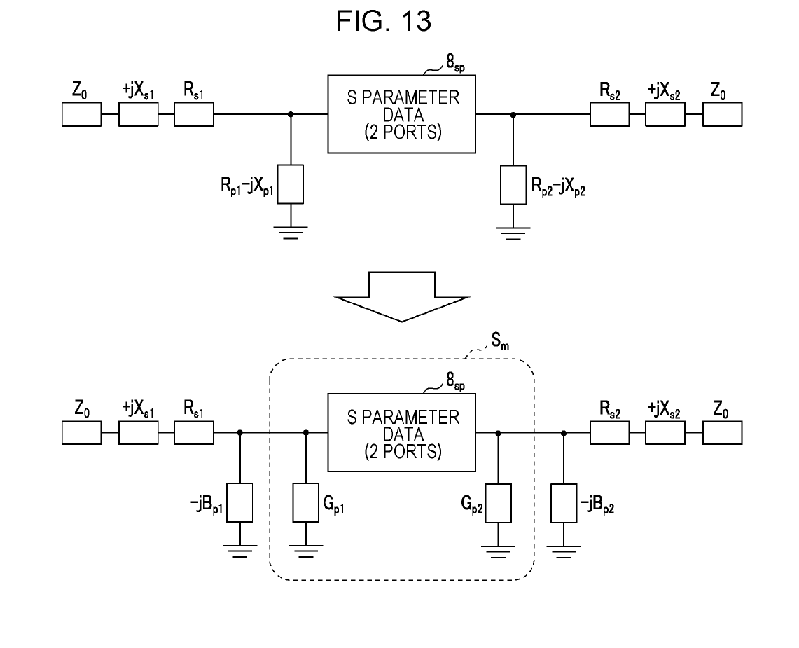

FIG. 13 is a diagram illustrating an example of a process in a case of the connection pattern No. 22. In FIG. 13, a model of an adjustment circuit in the connection pattern No. 22 is illustrated. In the connection pattern No. 22, the circuit element C is connected to the port 1 in parallel on the port 1 side and the circuit element L is connected in series and grounded on the wave source 1 side. The circuit element C connected to the port 1 in parallel is indicated by the circuit (Rₚ₁−jXₚ₁), and the circuit element L which is connected in series on the wave source 1 side and which is grounded is indicated by the circuit Rₛ₁ and the circuit+jXₛ₁.

Furthermore, the circuit element C is connected to the port 2 in parallel on the port 2 side and the circuit element L is connected in series and grounded on the wave source 2 side. The circuit element C connected to the port 2 in parallel is indicated by the circuit (Rₚ₂−jXₚ₂), and the circuit element L which is connected in series and which is grounded is indicated by the circuit Rₛ₂ and the circuit+jXₛ₂. Z₀(50) is given to the wave source 1 and the wave source 2.

Since a circuit element connected to the port 1 or the port 2 in series does not exist (NO in step S1304), the process in step S1305 is not performed. A result of the determination process in step S1306 is affirmative, and therefore, the process in step S1307 is performed on the port 1 and the port 2.

The circuit (Rₚ₁−jXₚ₁) representing the circuit element C connected to the port 1 in parallel is converted into the circuit Gₚ₁ and the circuit −jBₚ₁ individually connected to the port 1 in parallel in accordance with Math. 4. Furthermore, the circuit (Rₚ₂−jXₚ₂) representing the circuit element C connected to the port 2 in parallel is converted into the circuit Gₚ₂ and the circuit −jBₚ₂ individually connected to the port 2 in parallel in accordance with Math. 4. Then combined S parameter data Sₘ is obtained by combining the loss portion (Gₚ₁) and the loss portion (Gₚ₂) with the S parameter data 8ₛₚ so that the combined S parameter data Sₘ is obtained (step S1307).

Accordingly, impedance at a time of matching circuit connection is calculated such that the impedance matches the combined S parameter data Sₘ obtained in step S1307 (step S1308). As a result, values of Xₛ₁, Xₚ₁, Xₛ₂, and Xₚ₂ are obtained.

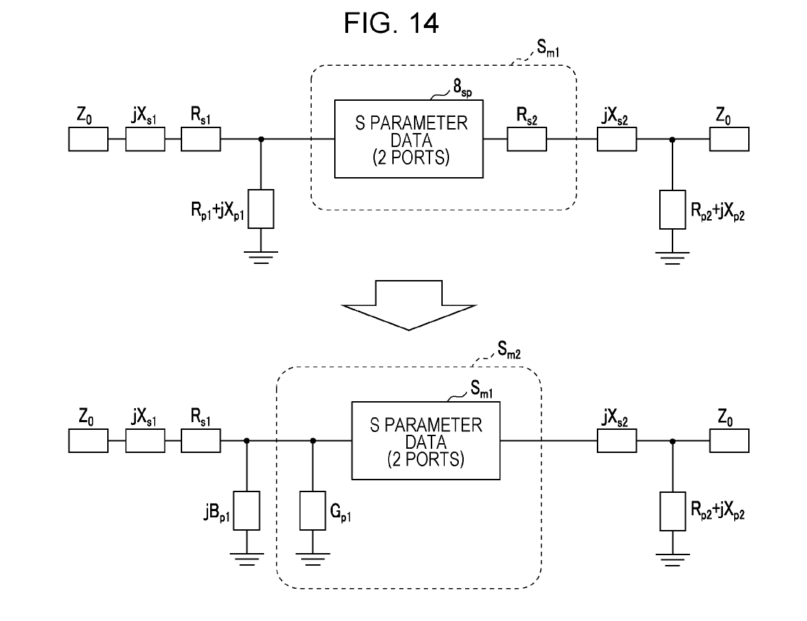

FIG. 14 is a diagram illustrating an example of a process in a case of the connection pattern No. 49. In FIG. 14, a model of an adjustment circuit in the connection pattern No. 49 is illustrated. In the connection pattern No. 49, the circuit element L is connected to the port 1 in parallel on the port 1 side and the circuit element L is connected in series and grounded on the wave source 1 side. The circuit element L connected to the port 1 in parallel is indicated by the circuit (Rₚ₁−jXₚ₁), and the circuit element L which is connected in series on the wave source 1 side and which is grounded is indicated by the circuit Rₛ₁ and the circuit+jXₛ₁.

Furthermore, the circuit element L is connected to the port 2 in series on the port 2 side and the circuit element L is connected in parallel and grounded on the wave source 2 side. The circuit element L connected to the port 2 in series is indicated by the circuit Rₛ₂ and the circuit jXₛ₂, and the circuit element L which is connected in parallel and which is grounded is indicated by the circuit (Rₚ₂+jXₚ₂). Z₀(50) is given to the wave source 1 and the wave source 2.

Since the circuit element L is connected to the port 2 in series (YES in step S1304), a loss portion (Rₛ₂) of the circuit element L connected to the port 2 in series is combined with the S parameter data 8ₛₚ so that combined S parameter data Sₘ₁ is obtained (step S1305).

Furthermore, since the circuit element L is connected to the port 1 in parallel (YES in step S1306), the circuit (Rₚ₁+jXₚ₁) representing the circuit element L connected to the port 1 in parallel is converted into the circuit Gₚ₁ and the circuit+jBₚ₁ individually connected to the port 1 in parallel in accordance with Math. 4. Then combined S parameter data Sₘ₂ is obtained by combining the loss portion (Gₚ₁) with the S parameter data Sₘ₁ obtained in step S1305 (step S1307).

Accordingly, impedance at a time of matching circuit connection is calculated such that the impedance matches the combined S parameter data Sₘ₂ obtained in step S1307 (step S1308). As a result, values of Xₛ₁, Xₚ₁, Xₛ₂, and Xₚ₂ are obtained.

As described with reference to FIGS. 12 to 14, according to this embodiment, at least a matching circuit which takes losses of circuit elements connected to the port 1 and the port 2 into consideration may be designed with higher accuracy when compared with the general techniques.

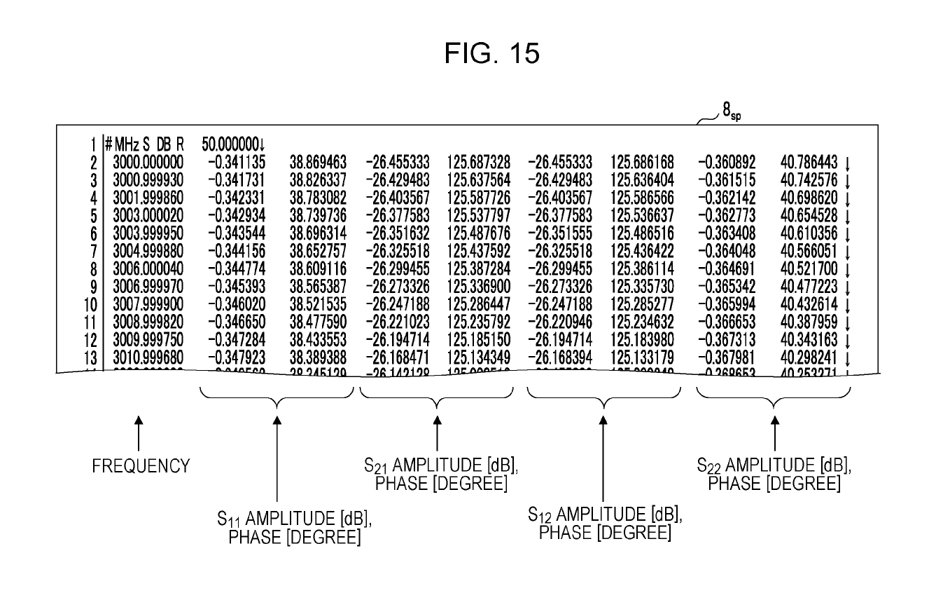

FIG. 15 is a diagram illustrating an example of S parameter data.

As illustrated in FIG. 15, the S parameter data 8ₛₚ includes values of an S₁₁ amplitude [dB] and a phase [degree], values of an S₂₁ amplitude [dB] and a phase [degree], values of an Sit amplitude [dB] and a phase [degree], and values of an S₂₂ amplitude [dB] and a phase [degree]. The S parameter data 8ₛₚ is a text file or the like.

Next, an example of a result of simulation of a general technique which does not take a loss of a matching circuit into consideration and an example of a result of simulation according to this embodiment which takes a loss of a matching circuit into consideration will be described below. A target frequency (a matching frequency) in the example of the simulation result below is 3.5 GHz. Furthermore, all circuit element constants indicating a loss are 1 Ohm (R=0 Ohm).

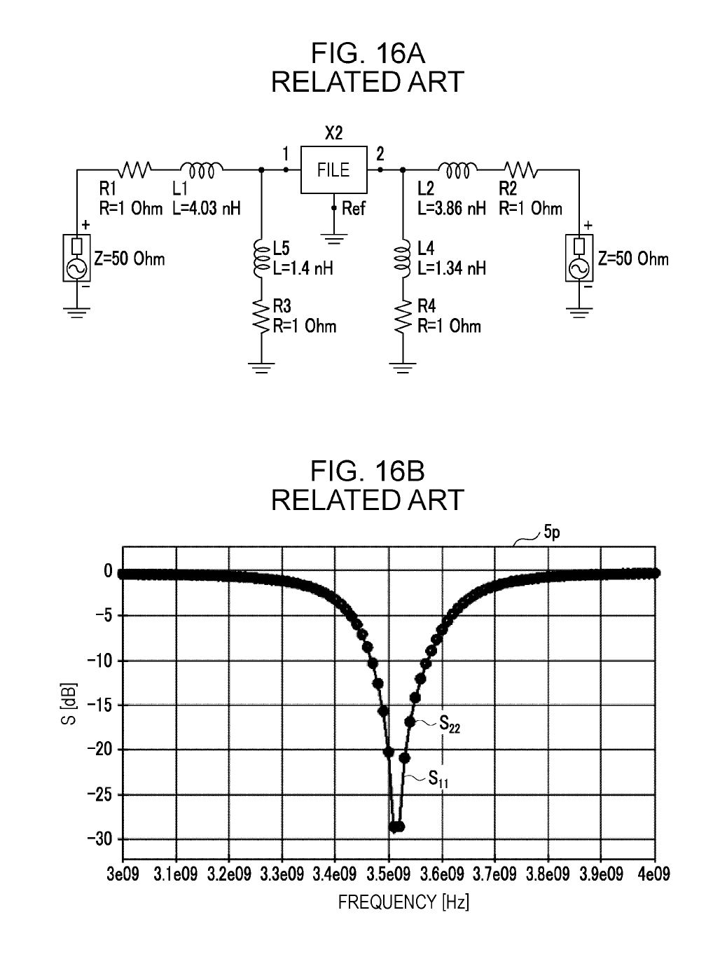

FIGS. 16A and 16B are diagrams illustrating an example of a result of simulation according to a general technique. FIG. 16A is a diagram illustrating a matching circuit which does not take a loss into consideration, and which includes inductances L1, L5, L2, and L4. According to FIG. 16A, L1 is 4.03 nH and L5 is 1.4 nH in a circuit on the port 1 side, and L2 is 3.86 nH and L4 is 1.34 nH in a circuit on the port 2 side.

In FIG. 16B, a graph 5p which includes an axis of ordinates indicating a reflection coefficient and an axis of abscissae indicating a frequency and which represents impedance at a time when a matching circuit of FIG. 16A is added is illustrated. A solid line indicates S₁₁ of the port 1, and dots indicate S₂₂ of the port 2. According to FIG. 16B, S₁₁ and S₂₂ at a frequency of 3.5 GHz in the matching circuit of FIG. 16A is approximately −20 dB.

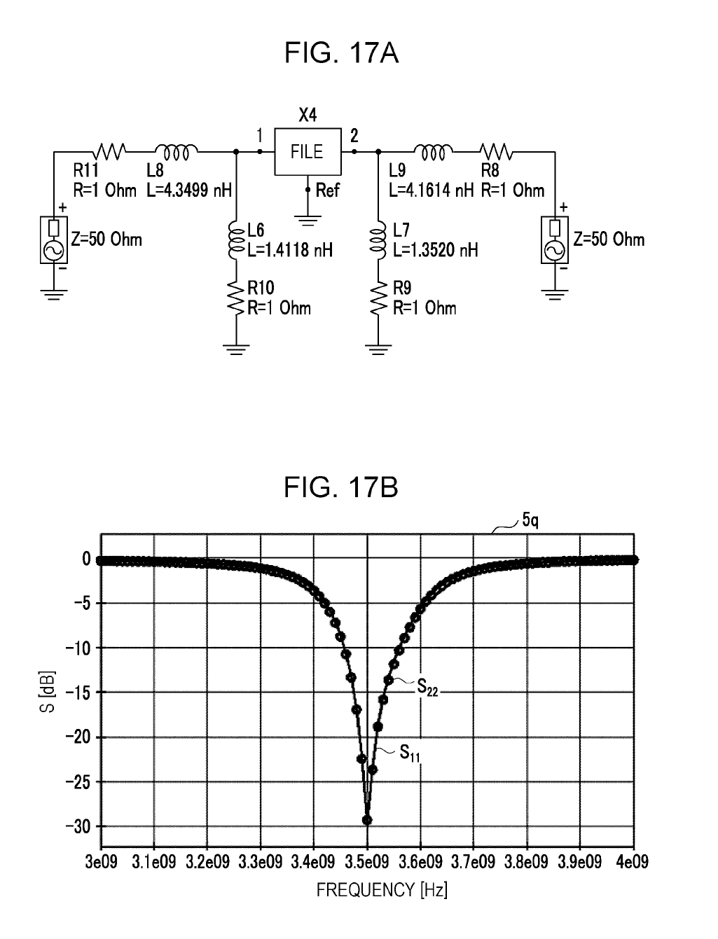

FIGS. 17A and 17B are diagrams illustrating an example of a result of simulation according to this embodiment. FIG. 17A is a diagram illustrating a matching circuit which takes a loss into consideration and which includes inductances L8, L6, L9, and L7. According to FIG. 17A, L8 is 4.3499 nH and L6 is 1.4118 nH in a circuit on the port 1 side, and L9 is 4.1614 nH and L7 is 1.3520 nH in a circuit on the port 2 side.

In FIG. 17B, a graph 5q which includes an axis of ordinates indicating a reflection coefficient and an axis of abscissae indicating a frequency and which represents impedance at a time when a matching circuit of FIG. 17A is added is illustrated. A solid line indicates S₁₁ of the port 1, and dots indicate S₂₂ of the port 2. According to FIG. 17B, S₁₁ and S₂₂ at a frequency of 3.5 GHz in the matching circuit of FIG. 17A is approximately −30 dB.

On the other hand, as described above, in the matching circuit of FIGS. 16A and 16B which does not take a loss into consideration, S₁₁ and S₂₂ at the frequency of 3.5 GHz is approximately −20 dB, and accordingly, matching is improved by approximately 10 dB according to this embodiment.

Furthermore, the designer only sets values suitable for an environment where the antenna apparatus 7 is installed in the conditional data 51 and does not perform a complicated parameter setting which required technical knowledge when compared with the case where numerical analysis is employed, and therefore, a burden of the designer for designing a matching circuit with high accuracy may be reduced.

Furthermore, as illustrated in FIGS. 10 and 11, optimum candidates of a matching circuit may be obtained by the calculation process using all the 64 connection patterns, and therefore, a period of time required for calculation may be reduced to approximately one several-tenth to one several-hundredth when compared with the case where the numerical analysis is employed. Accordingly, the calculation of the design of the matching circuit may be performed at high speed in this embodiment.

The present disclosure is not limited to the embodiment disclosed in detail and various modifications and changes may be made without departing from the scope of the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An antenna design apparatus comprising:
a memory; and
a processor coupled to the memory,
wherein the processor
calculates at least one circuit element value of a matching circuit for an antenna including loss resistance using S parameter data stored in the memory,
obtains combined S parameter data in which a portion of the loss resistance of the matching circuit is incorporated in characteristics of the antenna by calculating the S parameter data while loss resistance of one of the calculated at least one circuit element value of the matching circuit which is disposed on a port side is incorporated in the characteristics of the antenna, and
recalculates the at least one circuit element value of the matching circuit when the matching circuit is coupled to the antenna such that the at least one circuit element value matches the combined S parameter.

2. The antenna design apparatus according to claim 1, wherein the processor converts impedance into admittance when the matching circuit includes the impedance caused by parallel connection on the port side, and calculates the S parameter data while loss resistance obtained by the conversion is incorporated in the characteristics of the antenna so as to obtain the combined S parameter data.

3. The antenna design apparatus according to claim 1, wherein the processor calculates the S parameter data while loss resistance of impedance is incorporated in the characteristics of the antenna when the matching circuit includes the impedance caused by series connection on the port side so as to obtain the combined S parameter data.

4. The antenna design apparatus according to claim 2, wherein the combined S parameter data is obtained for each pattern of circuit configurations of the matching circuit, the impedance is recalculated, and the patterns are sorted in descending order of a bandwidth of the recalculated impedance.

5. The antenna design apparatus according to claim 4, wherein the processor outputs a circuit configuration of a widest bandwidth.

6. The antenna design apparatus according to claim 2, wherein the combined S parameter data is obtained for each pattern of circuit configurations of the matching circuit, the impedance is recalculated, a Q factor is calculated using the combined S parameter data, and the patterns are sorted in ascending order of the Q factor.

7. The antenna design apparatus according to claim 1, wherein the antenna is a 2-port antenna.

8. A non-transitory computer-readable recording medium storing therein a program for causing a computer to execute a process, the process comprising:
calculating at least one circuit element value of a matching circuit for an antenna including loss resistance using S parameter data stored in the memory;
obtaining combined S parameter data in which a portion of the loss resistance of the matching circuit is incorporated in characteristics of the antenna by calculating the S parameter data while loss resistance of one of the calculated at least one circuit element value of the matching circuit which is disposed on a port side is incorporated in the characteristics of the antenna; and
recalculating the at least one circuit element value of the matching circuit when the matching circuit is coupled to the antenna such that the at least one circuit element value matches the combined S parameter.

9. An antenna design method executed by a computer, comprising:
calculating at least one circuit element value of a matching circuit for an antenna including loss resistance using S parameter data stored in the memory;
obtaining combined S parameter data in which a portion of the loss resistance of the matching circuit is incorporated in characteristics of the antenna by calculating the S parameter data while loss resistance of one of the calculated at least one circuit element value of the matching circuit which is disposed on a port side is incorporated in the characteristics of the antenna; and
recalculating the at least one circuit element value of the matching circuit when the matching circuit is coupled to the antenna such that the at least one circuit element value matches the combined S parameter.
